(19) United States
(12) Patent Application Publication
(10) Pub. No.: US 2019/0296084 A1
(43) Pub. Date: Sep. 26, 2019

(54) STORAGE DEVICE

(71) Applicant: TOSHIBA MEMORY CORPORATION, Tokyo (JP)

(72) Inventors: Shota MOMBETSU, Yokkaichi Mie (JP); Akira YOTSUMOTO, Yokkaichi Mie (JP); Tetsu MOROOKA, Yokkaichi Mie (JP); Mutsumi OKAJIMA, Yokkaichi Mie (JP)

(73) Assignee: TOSHIBA MEMORY CORPORATION, Tokyo (JP)

(21) Appl. No.: 16/123,022

(22) Filed: Sep. 6, 2018

(30) Foreign Application Priority Data
Mar. 22, 2018 (JP) 2018-055380

(51) Int. Cl. H01L 27/24; G11C 13/00

(52) U.S. Cl. CPC H01L 27/2481; H01L 45/16; G11C 13/0028; G11C 13/0026

(57) ABSTRACT

A storage device includes a substrate; a plurality of insulating layers extending in a first direction; a plurality of first conductive layers extending in the first direction, and stacked alternately with the plurality of insulating layers along a second direction that intersects the first direction and is perpendicular to the substrate; a second conductive layer extending in the second direction; a recording layer provided between the second conductive layer and the plurality of first conductive layers; a first transistor electrically connected to the second conductive layer; a second transistor provided adjacent to the first transistor in a third direction that intersects the first direction and the second direction and is parallel to the substrate; and a first insulator provided on the second transistor.

### CROSS-REFERENCE TO RELATED APPLICATION

This application is based on and claims the benefit of Japanese Patent Application No. 2018-055380, filed Mar. 22, 2018, the entire contents of which are incorporated herein by reference.

### FIELD

Embodiments described herein relate generally to a storage device.

### BACKGROUND

As a large-capacity non-volatile memory, development on a two-terminal resistive random access memory, instead of a floating gate-type NAND flash memory in a related art, is being actively performed. For this type of memory, it is possible to achieve low-voltage and low-current operations, high speed switching, and miniaturization and high integration of a memory cell.

For a variable resistance layer of the resistive random access memory, various materials have been suggested.

In a large capacity memory array, a large number of metal wirings called bit lines and word lines are arranged in an intersecting manner, and memory cells are formed at intersections between the bit lines and the word lines. Writing to one memory cell is performed when a voltage is applied to the bit line BL and the word line WL connected to the corresponding cell.

### DESCRIPTION OF THE DRAWINGS

FIG. 1 is a block diagram of a storage device according to an embodiment.

FIG. 2 is an equivalent circuit diagram of a memory cell array according to the embodiment.

FIG. 3 is a schematic view of the storage device according to the embodiment.

FIG. 4 is a schematic view of the storage device according to the embodiment.

FIGS. 5A to 5F are schematic views illustrating apart of a method of manufacturing the storage device according to the embodiment.

FIG. 6 is a schematic sectional view illustrating a storage device during manufacturing, in a method of manufacturing the storage device according to the embodiment.

FIG. 7 is a schematic sectional view illustrating the storage device during manufacturing, in a method of manufacturing the storage device according to the embodiment.

FIG. 8 is a schematic sectional view illustrating the storage device during manufacturing, in a method of manufacturing the storage device according to the embodiment.

FIG. 9 is a schematic sectional view illustrating the storage device during manufacturing, in a method of manufacturing the storage device according to the embodiment.

FIG. 10 is a schematic sectional view illustrating the storage device during manufacturing, in a method of manufacturing the storage device according to the embodiment.

### DETAILED DESCRIPTION

Embodiments descried herein provide for a storage device with improved characteristics.

In general, according to one embodiment, a storage device includes: a substrate; a plurality of insulating layers extending in a first direction; a plurality of first conductive layers extending in the first direction, and stacked alternately with the plurality of insulating layers along a second direction that intersects the first direction and is perpendicular to the substrate; a second conductive layer extending in the second direction; a recording layer provided between the second conductive layer and the plurality of first conductive layers; a first transistor electrically connected to the second conductive layer; a second transistor provided adjacent to the first transistor in a third direction that intersects the first direction and the second direction and is parallel to the substrate; and a first insulator provided on the second transistor.

Hereinafter, an embodiment will be described with reference to the drawings. In the drawings, the same or similar portions (e.g. devices, components, parts, or portions thereof) are denoted by a same or similar reference labels and numerals.

In the present specification, in order to indicate a positional relationship between components or the like, an upward direction of the drawing is described as “upper,” and a downward direction of the drawing is described as “lower.” In the present specification, the concept on “upper,” and “lower” does not necessarily correspond to a term indicating a relationship with a direction of gravity.

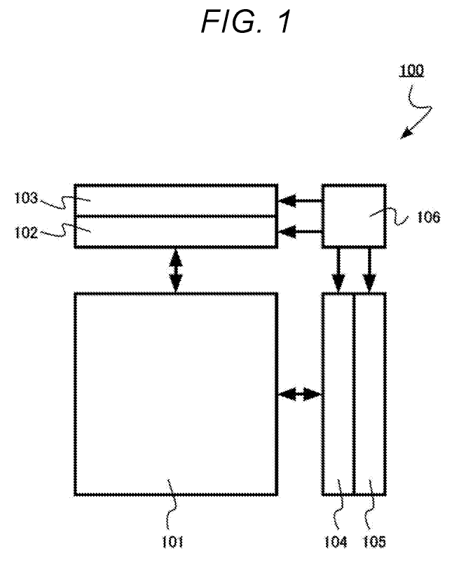

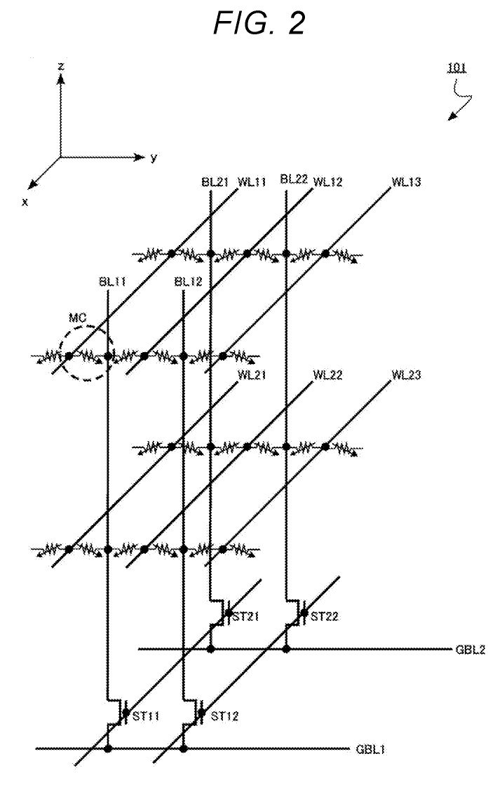

FIG. 1 is a block diagram of a storage device 100 according to the present embodiment. FIG. 2 is an equivalent circuit diagram of a memory cell array 101. FIG. 2 schematically illustrates a wiring structure within a memory cell array.

The storage device 100 of the present embodiment is a resistive random access memory. The resistive random access memory stores data using a resistance change of a recording layer which is caused by an application of a voltage.

The memory cell array 101 of the present embodiment includes a three-dimensional structure in which memory cells are three-dimensionally arranged. Since the three-dimensional structure is provided, the degree of integration of the storage device 100 is improved.

As illustrated in FIG. 1, the storage device 100 includes a memory cell array 101, a word line driver circuit 102, a row decoder circuit 103, a sense amplifier circuit 104, a column decoder circuit 105, and a control circuit 106.

As illustrated in FIG. 2, within the memory cell array 101, a plurality of memory cells MC are three-dimensionally arranged. In FIG. 2, a region surrounded by a broken line corresponds to one memory cell MC.

The memory cell array 101 includes, for example, a plurality of word lines WL (WL11, WL12, WL13, WL21, WL22, and WL23) and a plurality of bit lines BL (BL11, BL12, BL21, and BL22). The word lines WL extend in an x direction. The bit lines BL extend in a z direction perpendicularly intersecting the x direction. The memory cells MC are arranged at intersections between the word lines WL and the bit lines BL.

The x direction, the z direction perpendicularly intersecting the x direction, and a y direction perpendicularly intersecting the x direction and the z direction are specific examples of a first direction, a second direction, and a third direction, respectively.

The plurality of word lines WL are electrically connected to the row decoder circuit 103. The plurality of bit lines BL are connected to the sense amplifier circuit 104. Select transistors ST (ST11, ST21, ST12, and ST22) and global bit lines GBL (GBL1 and GBL2) are provided between the plurality of bit lines BL and the sense amplifier circuit 104. The global bit lines GBL are an example of a third conductive layer.

The row decoder circuit 103 has a function of selecting a word line WL according to an input row address signal. The word line driver circuit 102 has a function of applying a predetermined voltage to the word line WL selected by the row decoder circuit 103.

The column decoder circuit 105 has a function of selecting a bit line BL according to an input column address signal. The sense amplifier circuit 104 has a function of applying a predetermined voltage to the bit line BL selected by the column decoder circuit 105. The sense amplifier circuit 104 has a function of detecting and amplifying a current flowing between the selected word line WL and the selected bit line BL.

The control circuit 106 has a function of controlling the word line driver circuit 102, the row decoder circuit 103, the sense amplifier circuit 104, the column decoder circuit 105, and other circuits (not illustrated).

Circuits such as the word line driver circuit 102, the row decoder circuit 103, the sense amplifier circuit 104, the column decoder circuit 105, and the control circuit 106 are electronic circuits. For example, the circuits are configured with transistors and wiring layers using a semiconductor layer (not illustrated).

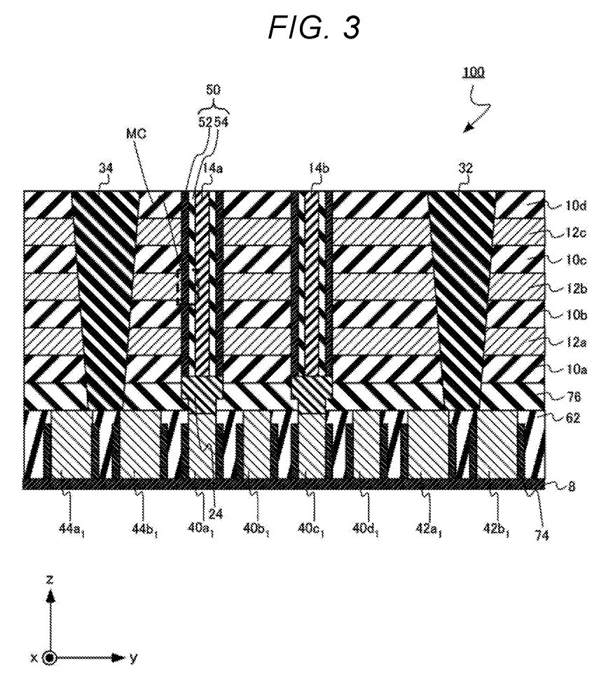

FIG. 3 is a schematic view of the storage device 100 according to the embodiment.

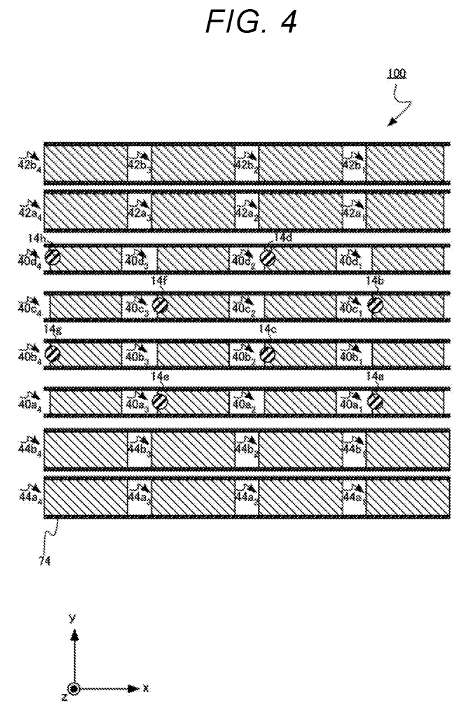

FIG. 4 is a schematic view of the storage device 100 according to the embodiment.

FIG. 3 is a schematic sectional view of the storage device 100 according to the embodiment, on a yz plane. FIG. 4 is a schematic view illustrating an arrangement of a first transistor 40, a first dummy transistor 42, a second dummy transistor 44, and a second conductive layer 14 in the storage device 100 according to the embodiment, on an xy plane. The first dummy transistor 42 and the second dummy transistor 44 are transistors not connected to a bit line BL. In FIG. 4, illustration of a substrate 8, an insulator 62, a stopper 76, a plurality of insulating layers 10a, 10b, 10c and 10d, a plurality of first conductive layers 12a, 12b, and 12c, a first insulator 34, a second insulator 32, and a recording layer 50 is omitted.

The substrate 8 is, for example, a Si (silicon) substrate or a Ge (germanium) substrate as a single crystal semiconductor substrate, a GaAs (gallium arsenide) substrate, a GaN (gallium nitride) substrate, or a SiC (silicon carbide) substrate as a compound semiconductor substrate, or the like. The substrate 8 may be, for example, an insulator substrate such as a SiO₂ (silicon oxide) substrate. The substrate 8 is provided parallel to the xy plane.

The plurality of insulating layers 10a, 10b, 10c and 10d are provided on the substrate 8, and extend in the x direction parallel to the surface of the substrate 8.

The plurality of insulating layers 10a, 10b, 10c and 10d include, for example, oxide, oxynitride or nitride. The plurality of insulating layers 10a, 10b, 10c and 10d include, for example, silicon oxide (SiO).

The plurality of first conductive layers 12a, 12b, and 12c extend in the x direction. The plurality of first conductive layers 12a, 12b, and 12c and the plurality of insulating layers 10a, 10b, 10c and 10d are alternately stacked along the z direction.

A second conductive layer 14a and a second conductive layer 14b (also referred to as a fourth conductive layer 14b) extend in the z direction, and extend through the plurality of insulating layers 10a, 10b, 10c and 10d, and the plurality of first conductive layers 12a, 12b, and 12c.

The plurality of first conductive layers 12a, 12b, and 12c, and the second conductive layers 14a and 14b are conductive layers. The plurality of first conductive layers 12a, 12b, and 12c, and the second conductive layers 14a and 14b are, for example, metal layers. The plurality of first conductive layers 12a, 12b, and 12c, and the second conductive layers 14a and 14b include, for example, tungsten, titanium nitride, or copper. The plurality of first conductive layers 12a, 12b, and 12c, and the second conductive layers 14a and 14b may include a conductive material such as other metals, a metal semiconductor compound, or a semiconductor.

The number of the plurality of insulating layers 10, the number of the plurality of first conductive layers 12, and the number of the plurality of second conductive layers 14 are not limited to those as described above.

The recording layer 50 is provided between the second conductive layer 14a, and the plurality of first conductive layers 12a, 12b, and 12c and the plurality of insulating layers 10a, 10b, 10c and 10d. The recording layer 50 is also provided between the second conductive layer 14b, and the plurality of first conductive layers 12a, 12b, and 12c and the plurality of insulating layers 10a, 10b, 10c and 10d.

The recording layer 50 has a function of storing data according to a change of a resistance state. The recording layer 50 is capable of re-writing data by an application of a voltage or a current. The recording layer 50 transitions between a high resistance state (a reset state) and a low resistance state (a set state) by an application of a voltage or a current. For example, the high resistance state is defined as data “0,” and the low resistance state is defined as data “1.”

The recording layer 50 includes a first recording layer 52. The recording layer includes a second recording layer 54 provided between the first recording layer 52 and the second conductive layer 14a, or between the first recording layer 52 and the second conductive layer 14b.

The first recording layer 52 includes, for example, silicon or germanium. The first recording layer 52 includes, for example, silicon, silicon germanium, or germanium. The first recording layer 52 includes, for example, amorphous silicon. The film thickness of the first recording layer 52 maybe about 3.5 nanometers (nm) or more which can help to obtain a good film quality, or may be about 10 nm or less which can help to prevent an increase of an operating voltage. The film thickness of the first recording layer 52 may be in a range of about 3.5 nm to about 10 nm.

The second recording layer 54 includes titanium oxide, tungsten oxide, or niobium oxide. The film thickness of the second recording layer 54 may be, for example, about 6 nm or more (e.g. about 7 nm or more, about 8 nm or more, or about 9 nm or more) which can help to obtain a good crystallinity.

The recording layer 50 may be a layer that includes, for example, chalcogenide, such as a Ge₂Sb₂Te₅ alloy.

In FIG. 3, a portion indicated by a broken line corresponds to one memory cell MC.

Referring to FIG. 4, a plurality of transistors are show. FIG. 4 shows a first transistor 40a₁ (a first transistor), a first transistor 40b₁ (a fourth transistor), a first transistor 40c₁ (a fifth transistor), a first transistor 40d₁, a first transistor 40a₂, a first transistor 40b₂ (a sixth transistor), a first transistor 40c₂, a first transistor 40d₂, a first transistor 40a₃, a first transistor 40b₃, a first transistor 40c₃, a first transistor 40d₃, a first transistor 40a₄, a first transistor 40b₄, a first transistor 40c₄ and a first transistor 40d₄, a first dummy transistor 42a₁ (a third transistor), a first dummy transistor 42b₁, a first dummy transistor 42a₂, a first dummy transistor 42b₂, a first dummy transistor 42a₃, a first dummy transistor 42b₃, a first dummy transistor 42a₄, and a first dummy transistor 42b₄, a second dummy transistor 44a₁, a second dummy transistor 44b₁ (a second transistor), a second dummy transistor 44a₂, a second dummy transistor 44b₂, a second dummy transistor 44a₃, a second dummy transistor 44b₃, a second dummy transistor 44a₄, and a second dummy transistor 44b₄ provided between the substrate 8 and the insulating layer 10.

The first transistors 40a₁, 40b₁, 40c₁, and 40d₁ are provided between the first dummy transistors 42a₁ and 42b₁, and the second dummy transistors 44a₁ and 44b₁. The first transistors 40a₂, 40b₂, 40c₂, and 40d₂ are provided between the first dummy transistors 42a₂ and 42b₂, and the second dummy transistors 44a₂ and 44b₂. The first transistors 40a₃, 40b₃, 40c₃, and 40d₃ are provided between the first dummy transistors 42a₃ and 42b₃, and the second dummy transistors 44a₃ and 44b₃. The first transistors 40a₄, 40b₄, 40c₄, and 40d₄ are provided between the first dummy transistors 42a₄ and 42b₄, and the second dummy transistors 44a₄ and 44b₄.

Specifically, as illustrated in FIG. 3, the second dummy transistor 44b₁ (the second transistor) is provided adjacent to the first transistor 40a₁ (the first transistor) in the y direction. The first transistor 40a₁ (the first transistor) is provided between the second dummy transistor 44b₁ (the second transistor) and the first dummy transistor 42a₁ (the third transistor) in the y direction. The first transistor 40b₁ (the fourth transistor) is adjacent to the first transistor 40a₁ (the first transistor) in the y direction, and is provided between the first transistor 40a₁ (the first transistor) and the first dummy transistor 42a₁ (the third transistor). The first transistor 40c₁ (the fifth transistor) is adjacent to the first transistor 40b₁ (the fourth transistor) in they direction, and is provided between the first transistor 40b₁ (the fourth transistor) and the first dummy transistor 42a₁ (the third transistor). The first transistor 40b₂ (the sixth transistor) is provided adjacent to the first transistor 40b₁ (the fourth transistor) in the x direction.

The first transistor 40a₁ is electrically connected to the second conductive layer 14a. The first transistor 40c₁ is electrically connected to the second conductive layer 14b. The first transistor 40b₂ is electrically connected to a second conductive layer 14c (a fifth conductive layer 14c). The first transistor 40d₂ is electrically connected to a second conductive layer 14d. The first transistor 40a₃ is electrically connected to a second conductive layer 14e. The first transistor 40c₃ is electrically connected to a second conductive layer 14f. The first transistor 40b₄ is electrically connected to a second conductive layer 14g. The first transistor 40d₄ is electrically connected to a second conductive layer 14h. In some embodiments, the first dummy transistors 42 and the second dummy transistors 44 are not electrically connected to any of the second conductive layers 14.

In the arrangement within the xy plane as illustrated in FIG. 4, the second conductive layer 14b is provided aligned with the second conductive layer 14a in the y direction (e.g. in a direction along which the first transistors 40, the first dummy transistors 42, and the second dummy transistors 44 are arrayed).

The second conductive layer 14c is provided between the second conductive layer 14a and the second conductive layer 14b in they direction. Meanwhile, the second conductive layer 14c is provided shifted from the second conductive layer 14a and the second conductive layer 14b in the x direction (e.g. in a direction along which a gate metal 74 extends). That is, the second conductive layer 14c is not provided between the second conductive layer 14a and the second conductive layer 14b in the x direction.

The second conductive layer 14d is provided aligned with the second conductive layer 14c in they direction. Then, the second conductive layer 14b is provided between the second conductive layer 14c and the second conductive layer 14d in the y direction. Meanwhile, the second conductive layer 14b is provided shifted from the second conductive layer 14c and the second conductive layer 14d in the x direction.

The second conductive layer 14f is provided between the second conductive layer 14c and the second conductive layer 14d in they direction. Meanwhile, the second conductive layer 14f is provided shifted from the second conductive layer 14c and the second conductive layer 14d and aligned with the second conductive layer 14b in the x direction.

The second conductive layer 14e is provided aligned with the second conductive layer 14a in the x direction. The second conductive layer 14e is provided aligned with the second conductive layer 14f in the y direction.

The second conductive layer 14g is provided between the second conductive layer 14e and the second conductive layer 14f in they direction. Meanwhile, the second conductive layer 14g is provided aligned with the second conductive layer 14c in the x direction but is not provided between the second conductive layer 14e and the second conductive layer 14f.

The second conductive layer 14h is provided aligned with the second conductive layer 14d in the x direction. The second conductive layer 14h is provided aligned with the second conductive layer 14g in the y direction.

The first transistor 40, the first dummy transistor 42, and the second dummy transistor 44 are thin film transistors (TFT).

The first transistor 40 is the select transistor ST illustrated in FIG. 2.

A gate metal 74 (third conductive layer), which includes, for example, titanium nitride, and functions as a gate electrode of a transistor, is provided in each of the first transistor 40, the first dummy transistor 42, and the second dummy transistor 44.

The stopper 76 including silicon nitride is provided between the insulating layer 10a, and the first transistor 40, the first dummy transistor 42, and the second dummy transistor 44. Each insulator 62 is provided between the first transistor 40, the first dummy transistor 42, and the second dummy transistor 44.

The first transistor 40, the first dummy transistor 42, and the second dummy transistor 44 may have approximately a same n-type impurity concentration and a same p-type impurity concentration which can help to facilitate manufacturing.

The first insulator 34 is provided on the second dummy transistors 44a₁, 44b₁, 44a₂, 44b₂, 44a₃, 44b₃, 44a₄, and 44b₄.

The first insulator 34 extends in the x direction and the z direction. The first insulator 34 is provided while extending through, for example, the plurality of insulating layers 10 and the plurality of first conductive layers 12. The first insulator 34 is an insulator. The first insulator 34 includes, for example, silicon oxide. The first insulator 34 may be tapered, and may include an upper portion and a lower portion (e.g. in the z direction), where the upper portion is wider (e.g. in the y direction) than the lower portion.

The second insulator 32 is provided on the first dummy transistors 42a₁, 42b₁, 42a₂, 42b₂, 42a₃, 42b₃, 42a₄, and 42b₄.

The second insulator 32 extends in the x direction and the z direction. The second insulator 32 is provided while extending through, for example, the plurality of insulating layers 10 and the plurality of first conductive layers 12. The second insulator 32 is an insulator. The second insulator 32 includes, for example, silicon oxide. The second insulator 32 may be tapered, and may include an upper portion and a lower portion (e.g. in the z direction), where the upper portion is wider (e.g. in the y direction) than the lower portion.

Instead of the second insulator 32 or the first insulator 34, for example, an electric circuit configured to drive a memory cell MC, or other electric circuits may be provided. A reinforcing material including, for example, nitride may be provided.

The length of the first dummy transistor 42 or the second dummy transistor 44 in the y direction may be longer than the length of the first transistor 40 in the y direction. Here, the length of the first dummy transistor 42, the length of the second dummy transistor 44, and the length of the first transistor 40 are, for example, channel widths.

Hereinafter, a method of manufacturing the storage device 100 according to the embodiment will be described. Although some of the processes of the method may be described as being performed in a specified chronological order, the embodiment is not limited so-limited, and processes of the method may be performed in a different order (including two or more of the processes being performed at a same time) than described herein.

The method of manufacturing the storage device 100 according to the embodiment includes: forming a plurality of insulating layers and a plurality of sacrifice layers provided between the plurality of insulating layers, on a first dummy transistor, a second dummy transistor, and a first transistor provided between the first dummy transistor and the second dummy transistor; forming a first hole on the first transistor through the plurality of insulating layers and the plurality of sacrifice layers; forming a recording layer within the first hole; forming a second conductive layer within the first hole so as to be electrically connected to the first transistor; forming a plurality of second holes on the first dummy transistor and the second dummy transistor through the plurality of insulating layers and the plurality of sacrifice layers; removing the plurality of sacrifice layers; forming first conductive layers in a portion from which the plurality of sacrifice layers are removed; and forming insulators within the plurality of second holes.

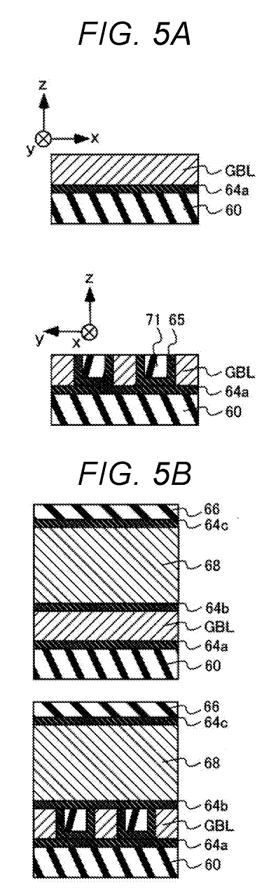

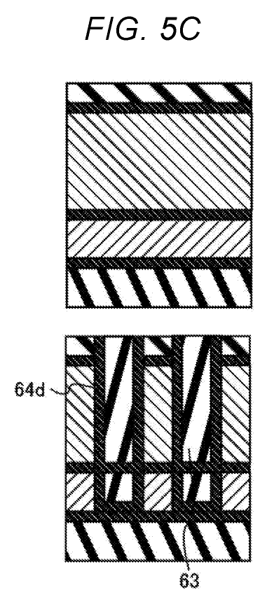

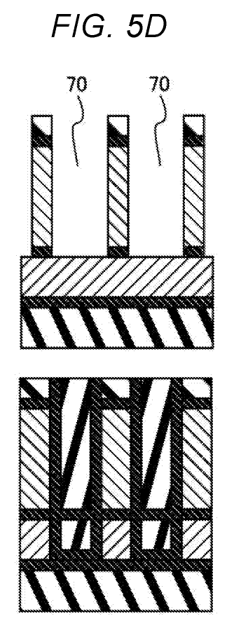

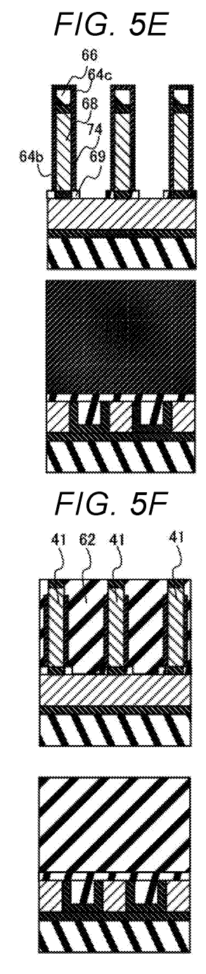

FIGS. 5A to 5F are schematic views illustrating a part of a method of manufacturing the storage device 100 according to the embodiment. FIGS. 5A to 5F are schematic views illustrating a method of manufacturing transistors (the first transistor 40, the first dummy transistor 42, and the second dummy transistor 44) of the storage device 100 according to the embodiment. In each of FIGS. 5A to 5F, two drawings are illustrated in the vertical direction, in which one drawing illustrated at the upper side in the drawing is a schematic view illustrating a part of a manufacturing process, on an xz plane, and the other drawing illustrated at the lower side in the drawing is a schematic view illustrating a part of a manufacturing process, on a yz plane.

First, a tungsten (W)-containing film that includes tungsten is formed on an oxide film 60 provided on the substrate 8 (not illustrated) via a barrier metal 64a. Next, a plurality of grooves are formed in the tungsten (W)-containing film to extend in the x direction. Next, a barrier metal 65 including titanium nitride (TiN) is formed within each of the plurality of grooves. Next, an insulator 71 including, for example, silicon oxide (SiO) is formed within the groove formed with the barrier metal 65. At least a portion of the tungsten (W)-containing film becomes a global bit line GBL. A wiring (not illustrated) may be formed within the oxide film 60 (FIG. 5A).

Next, a barrier metal 64b, polysilicon 68, a barrier metal 64c, and a stopper 66 including silicon nitride (SiN) are sequentially formed on the global bit line GBL, the insulator 71, and the barrier metal 65 (FIG. 5B).

Next, a portion of the barrier metal 64b, a portion of the polysilicon 68, a portion of the barrier metal 64c, and a portion of the stopper 66, formed on the insulator 71, are removed by lithography and reactive ion etching (RIE) to form grooves extending in the x direction. Next, a barrier metal 64d is formed within each of the grooves, and then, an insulator 63 including, for example, silicon oxide is formed (FIG. 5C).

Next, a portion of the barrier metal 64b, a portion of the polysilicon 68, a portion of the barrier metal 64c, and a portion of the stopper 66, formed on the insulator 71, are removed by lithography and reactive ion etching (RIE) to form grooves 70 extending in the y direction (FIG. 5D).

Next, an insulator 69 is formed on the side surface of the barrier metal 64b. Next, a titanium nitride-containing gate metal 74 that includes titanium nitride is formed on the insulator 69 to cover a portion of the barrier metal 64b, a portion of the polysilicon 68, a portion of the barrier metal 64c, and a portion of the stopper 66 which remain without being removed (FIG. 5E).

Next, a portion of an upper portion of the gate metal 74 is removed. Then, a silicon oxide-containing insulator 62 that includes silicon oxide is formed within each of the grooves 70. Next, a portion of the stopper 66 and the insulator 62 is removed to obtain a transistor 41 (FIG. 5F). The transistor 41 becomes the first transistor 40, the first dummy transistor 42, or the second dummy transistor 44.

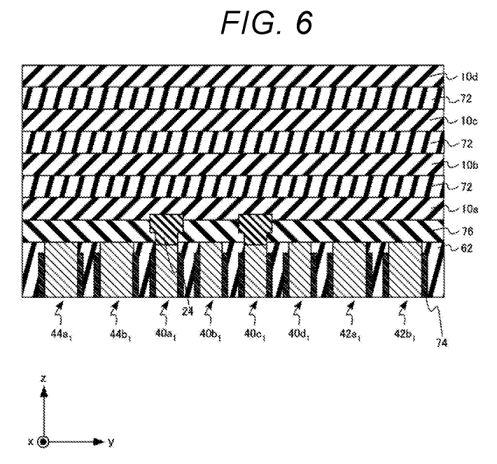

FIGS. 6 to 10 are schematic sectional views illustrating a storage device during manufacturing, in the method of manufacturing the storage device 100 according to the embodiment. Descriptions on the oxide film 60, the barrier metal 64a, the GBL, the insulator 69, the barrier metal 64b, and the barrier metal 64c, which are described in FIG. 5F, will be omitted.

First, the stopper 76 including silicon nitride is formed on the first transistor 40, the first dummy transistor 42, and the second dummy transistor 44, and a connection portion 24 including a conductive material is formed within the stopper 76. Next, the plurality of insulating layers 10 extending in the x direction, and a plurality of sacrifice layers 72 including, for example, oxide, oxynitride, or nitride, which are provided between the plurality of insulating layers 10 extending in the x direction, are formed on the stopper 76 and the connection portion 24 (FIG. 6).

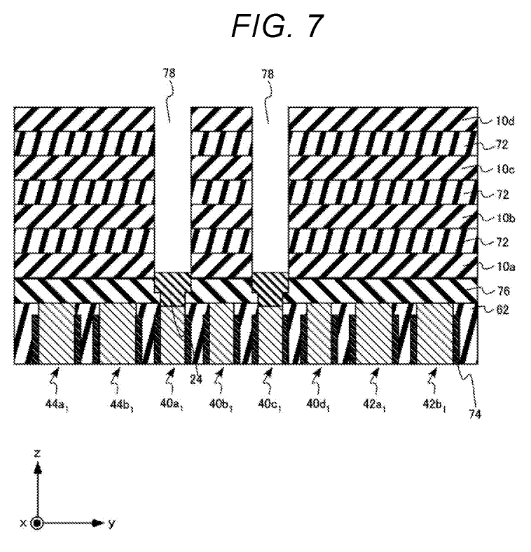

Next, a first hole 78 is formed on the first transistor 40 through the plurality of insulating layers 10 and the plurality of sacrifice layers 72 (FIG. 7).

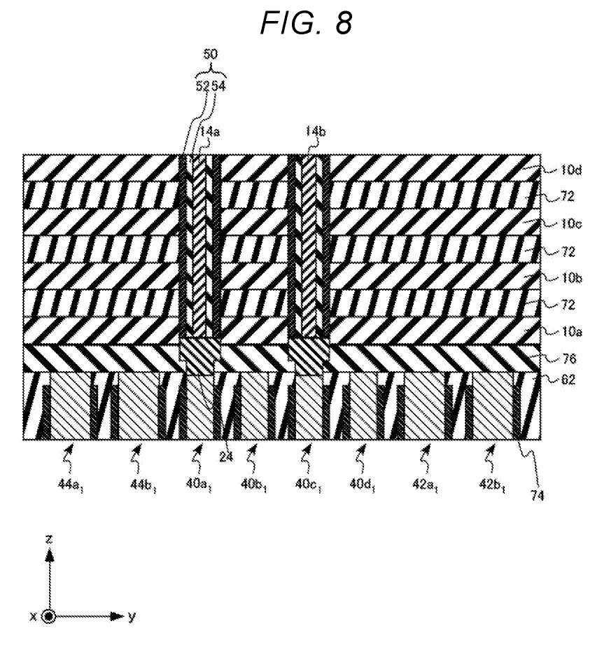

Next, the recording layer 50 (the first recording layer 52 and the second recording layer 54) is formed within the first hole 78. Next, the second conductive layer 14 (the second conductive layer 14a or the second conductive layer 14b) is formed within the first hole while extending in the z direction to be electrically connected to the first transistor 40 through the connection portion 24 (FIG. 8).

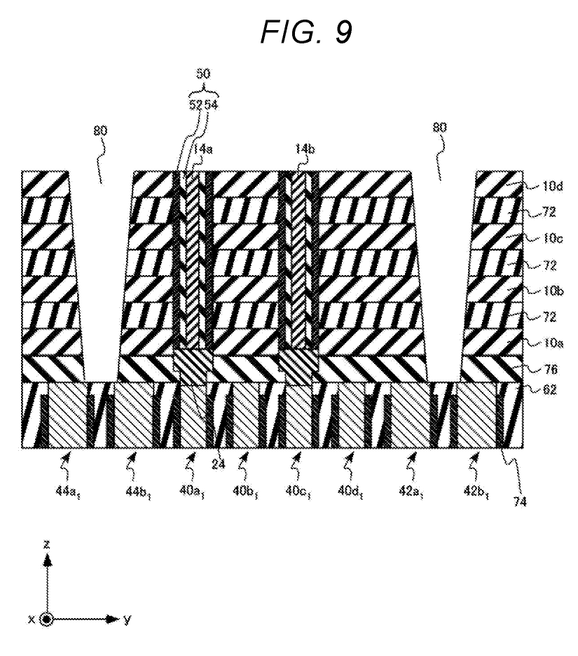

Next, a plurality of second holes 80 are formed on the first dummy transistor 42 (the first dummy transistor 42a₁ and the first dummy transistor 42b₁) and the second dummy transistor 44 (the second dummy transistor 44a₁ and the second dummy transistor 44b₁) through the plurality of insulating layers 10 and the plurality of sacrifice layers 72 (FIG. 9).

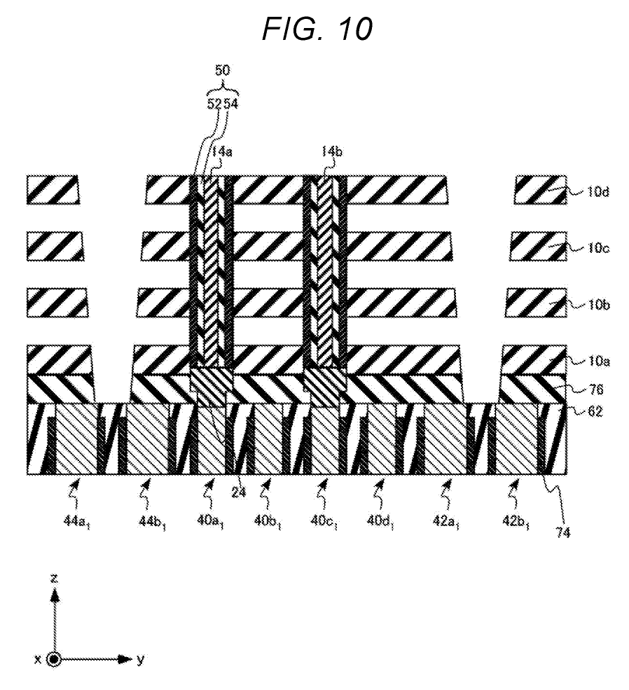

Next, the plurality of sacrifice layers 72 are removed by wet etching through the plurality of second holes 80 (FIG. 10).

Next, after a barrier metal (not illustrated) is formed in a portion from which the plurality of sacrifice layers 72 are removed (e.g. in one or more spaces generated by the removal of the sacrifice layers 72), tungsten is introduced through, for example, the second holes 80 to form the first conductive layers 12.

Next, the second insulator 32 and the first insulator 34 are formed within the plurality of second holes 80 to obtain the storage device 100 according to the embodiment.

Next, an operational effect of the storage device 100 according to the embodiment will be described.

Within a memory cell MC, a member or component other than the second conductive layer 14 or the memory cell MC may be provided.

For example, in order to form the first conductive layers 12, the sacrifice layers 72 may be formed, and then removed, and then tungsten may be introduced so that the first conductive layers 12 are formed. In this case, the second holes 80 through which tungsten is introduced may be formed at regular intervals in the y direction. The second holes 80 are filled up with the first insulator 34 or the second insulator 32 after tungsten is introduced. Thus, a memory cell MC is not provided around each of the second holes 80. Therefore, select transistors ST such as the first dummy transistor 42 and the second dummy transistor 44 may not be necessarily provided under the second holes 80.

However, when the select transistors ST (the first dummy transistor 42, the second dummy transistor 44) are not provided under the second holes 80, a variation may occur in the shape of the first transistor 40. The shape variation can occur, for example, in the first transistors 40a₁ and 40d₁ which are provided at locations closer to the second holes 80. Accordingly, characteristics of the first transistors 40a₁ and 40d₁ become different from those of other first transistors 40b₁ and 40c₁. Thus, an operation of memory cells MC connected to the first transistors 40a₁ and 40d₁ becomes different from an operation of memory cells MC connected to the first transistors 40b₁ and 40c₁.

Therefore, in the storage device 100 according to the embodiment, the first dummy transistor 42 is provided adjacent to the first transistor 40 in the y direction, and the second dummy transistor 44 is provided such that the first transistor is provided between the first dummy transistor 42 and the second dummy transistor 44. Then, the second insulator 32 is provided on the first dummy transistor 42, and the first insulator 34 is provided on the second dummy transistor 44.

When the first dummy transistor 42 and the second dummy transistor 44 are provided, the shapes of the first transistors 40a₁ and 40d₁ may become the same as those of other first transistors 40b₁ and 40c₁. This may reduce a characteristic variation of the first transistor 40, thereby providing the storage device 100 with a stable characteristic.

When the plurality of first dummy transistors 42 and the plurality of second dummy transistors 44 are provided, a shape variation of the first transistor 40 may be further reduced, thereby providing the storage device 100 with improved, stable characteristics.

The length of the first dummy transistor 42 or the second dummy transistor 44 may be made longer than the length of the first transistor 40 in the x direction or the y direction so as to stably form the first dummy transistor 42 or the second dummy transistor 44. This is because when the length of the first dummy transistor 42 or the second dummy transistor 44 is shortened, the first dummy transistor 42 or the second dummy transistor 44 may collapse during formation. Accordingly, the first transistor 40 may be stably formed.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

While certain embodiments have been described, these embodiments have been presented by way of example only, and are not intended to limit the scope of the present disclosure. Indeed, the embodiments described herein may be embodied in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. A storage device comprising:
a substrate;
a plurality of insulating layers extending in a first direction;
a plurality of first conductive layers extending in the first direction, and stacked alternately with the plurality of insulating layers along a second direction that intersects the first direction and is perpendicular to the substrate;
a second conductive layer extending in the second direction;
a recording layer provided between the second conductive layer and the plurality of first conductive layers;
a first transistor electrically connected to the second conductive layer;
a second transistor provided adjacent to the first transistor in a third direction that intersects the first direction and the second direction and is parallel to the substrate; and
a first insulator provided on the second transistor.

2. The storage device according to claim 1, wherein a length of the second transistor in the third direction is larger than a length of the first transistor in the third direction.

3. The storage device according to claim. 1, wherein the first insulator extends in the first direction and the second direction.

4. The storage device according to claim 1, wherein the first insulator extends through the plurality of first conductive layers.

5. The storage device according to claim 4, wherein the first insulator is tapered.

6. The storage device according to claim 1, further comprising:
a third transistor; and
a second insulator provided on the third transistor, and extending in the first direction and the second direction,
wherein the first transistor is provided between the second transistor and the third transistor.

7. The storage device according to claim 6, further comprising:
a third conductive layer extending in the third direction, and electrically connected to the first transistor, the second transistor, and the third transistor,
wherein the first transistor is provided between the second conductive layer and the third conductive layer.

8. The storage device according to claim 7, further comprising:
a fourth transistor adjacent to the first transistor in the third direction and provided between the first transistor and the third transistor;
a fifth transistor adjacent to the fourth transistor in the third direction and provided between the third transistor and the fourth transistor; and
a fourth conductive layer electrically connected to the fifth transistor, and extending in the second direction.

9. The storage device according to claim 8, further comprising:
a sixth transistor adjacent to the fourth transistor in the first direction; and
a fifth conductive layer that is electrically connected to the sixth transistor and extends in the second direction, the fifth conductive layer being provided between the second conductive layer and the fourth conductive layer in the third direction, and provided at a position different from the second conductive layer and the fourth conductive layer in the first direction.

10. The storage device according to claim 1, wherein the first transistor and the second transistor have approximately a same n-type impurity concentration and a same p-type impurity concentration.

11. The storage device according to claim 1, wherein the first transistor and the second transistor have approximately a same n-type impurity concentration and a same p-type impurity concentration.

12. The storage device according to claim 1, wherein a film thickness of the recording layer is in a range of about 3.5 nanometers (nm) to about 10 nm, and the recording layer is in contact with the plurality of first conductive layers and the second conductive layer.

13. A method of manufacturing a storage device, comprising:
forming a plurality of insulating layers and a plurality of sacrifice layers provided between the plurality of insulating layers, on a first dummy transistor, a second dummy transistor, and a first transistor provided between the first dummy transistor and the second dummy transistor;
forming a first hole on the first transistor through the plurality of insulating layers and the plurality of sacrifice layers;
forming a recording layer within the first hole;
forming a second conductive layer within the first hole so as to be electrically connected to the first transistor;
forming respective second holes on the first dummy transistor and the second dummy transistor through the plurality of insulating layers and the plurality of sacrifice layers;
removing the plurality of sacrifice layers to generate a plurality of spaces;
forming first conductive layers in the spaces; and
forming insulators within the plurality of second holes.

14. The method according to claim 13, wherein the second holes are formed to extend through the plurality of first conductive layers.

15. The method according to claim 14, wherein the second holes are tapered.

16. The method according to claim 13, further comprising:
forming the plurality of insulating layers and a plurality of sacrifice layers on a second transistor;
forming a third hole on the second transistor through the plurality of insulating layers and the plurality of sacrifice layers; and
forming a third conductive layer within the third hole so as to be electrically connected to the second transistor.

17. The method according to claim 16, wherein the first transistor and the second transistor are formed to have approximately a same n-type impurity concentration and a same p-type impurity concentration.

18. The method according to claim 13, wherein the recording layer is formed to have a film thickness in a range of about 3.5 nanometers (nm) to about 10 nm.

19. The method according to claim 13, wherein the sacrifice layers include oxide, oxynitride, or nitride.

20. The method according to claim 19, wherein the sacrifice layers are removed by wet etching.
